(19) United States
(12) Patent Application Publication
(10) Pub. No.: US 2025/0008756 A1
(43) Pub. Date: Jan. 2, 2025

(54) DETECTION DEVICE

(71) Applicant: Japan Display Inc., Tokyo (JP)

(72) Inventors: Shinya ASAKURA, Tokyo (JP); Jun NITTA, Tokyo (JP)

(21) Appl. No.: 18/883,640

(22) Filed: Sep. 12, 2024

Related U.S. Application Data
(63) Continuation of application No. PCT/JP2023/008442, filed on Mar. 7, 2023.

(30) Foreign Application Priority Data
Mar. 16, 2022 (JP) 2022-041829

(51) Int. Cl. H10K 39/30

(52) U.S. Cl. CPC H10K 39/30

(57) ABSTRACT

According to an aspect, a detection device includes: a sensor including a first photodiode and a second photodiode; and a detection circuit configured to alternately detect an output of the first photodiode and an output of the second photodiode. Anodes of the first photodiode and the second photodiode are configured to be supplied with a first potential. A cathode of the second photodiode is configured to be supplied with a second potential lower than the first potential in a first period in which the output of the first photodiode is detected. A cathode of the first photodiode is configured to be supplied with the second potential in a second period in which the output of the second photodiode is detected.

### CROSS-REFERENCE TO RELATED APPLICATION

This application claims the benefit of priority from Japanese Patent Application No. 2022-041829 filed on Mar. 16, 2022 and International Patent Application No. PCT/JP2023/008442 filed on Mar. 7, 2023, the entire contents of which are incorporated herein by reference.

### BACKGROUND

### 1. Technical Field

What is disclosed herein relates to a detection device.

### 2. Description of the Related Art

For example, detection devices each using an optical sensor for detection are known (refer to Japanese Patent Application Laid-open No. 2011-010054, for example). Such a detection device using an optical sensor performs a detection process by converting an electric charge generated by reverse-biasing the optical sensor into a voltage signal, outputting the voltage signal to a detection circuit, and integrating the voltage signal with an integrating circuit provided in the detection circuit.

As the optical sensor for detection, for example, organic photodetectors such as organic photodiodes (OPDs) are known. When variations occur in an organic semiconductor layer in a detection device using an OPD, variations occur in reverse-bias characteristics. In addition, the reverse-bias characteristics may change over time to reduce accuracy of detection.

For the foregoing reasons, there is a need for a detection device that can restrain the reduction in accuracy of detection due to the change over time of the reverse-bias characteristics.

### SUMMARY

According to an aspect, a detection device includes: a sensor including a first photodiode and a second photodiode; and a detection circuit configured to alternately detect an output of the first photodiode and an output of the second photodiode. Anodes of the first photodiode and the second photodiode are configured to be supplied with a first potential. A cathode of the second photodiode is configured to be supplied with a second potential lower than the first potential in a first period in which the output of the first photodiode is detected. A cathode of the first photodiode is configured to be supplied with the second potential in a second period in which the output of the second photodiode is detected.

### BRIEF DESCRIPTION OF THE DRAWINGS

FIG. 1A is a sectional view illustrating a schematic sectional configuration of a detection apparatus having an illumination device, the detection apparatus including a detection device according to an embodiment;

FIG. 1B is a sectional view illustrating a schematic sectional configuration of a detection apparatus having an illumination device according to a modification;

FIG. 2 is a plan view illustrating the detection device according to a comparative example;

FIG. 3 is a diagram illustrating a configuration in each divided area of the detection device according to a comparative example and an example of coupling to a detection circuit;

FIG. 4 is a timing diagram illustrating an operation example of the detection device according to the comparative example;

FIG. 5 is a diagram illustrating an example of diode characteristics of an optical sensor;

FIG. 6A is a diagram illustrating an example in which an output level in each divided area is visualized in a detection area;

FIG. 6B is a diagram illustrating another example in which the output level in each divided area is visualized in the detection area;

FIG. 7 is a plan view illustrating the detection device according to the embodiment;

FIG. 8 is a diagram illustrating a configuration in each divided area of the detection device according to the embodiment and an example of coupling to the detection circuit;

FIG. 9 is a timing diagram illustrating an operation example of the detection device according to the embodiment;

FIG. 10 is a plan view illustrating a detection device according to a first modification of the embodiment; and

FIG. 11 is a plan view illustrating a detection device according to a second modification of the embodiment.

### DETAILED DESCRIPTION

The following describes a mode (embodiment) for carrying out the present disclosure in detail with reference to the drawings. The present disclosure is not limited to the description of the embodiment given below. Components described below include those easily conceivable by those skilled in the art or those substantially identical thereto. In addition, the components described below can be combined as appropriate. What is disclosed herein is merely an example, and the present disclosure naturally encompasses appropriate modifications easily conceivable by those skilled in the art while maintaining the gist of the present disclosure. To further clarify the description, the drawings may schematically illustrate, for example, widths, thicknesses, and shapes of various parts as compared with actual aspects thereof. However, they are merely examples, and interpretation of the present disclosure is not limited thereto. The same element as that illustrated in a drawing that has already been discussed is denoted by the same reference numeral through the description and the drawings, and detailed description thereof may not be repeated where appropriate.

In the present specification and claims, in expressing an aspect of disposing another structure on or above a certain structure, a case of simply expressing “on” includes both a case of disposing the other structure immediately on the certain structure so as to contact the certain structure and a case of disposing the other structure above the certain structure with still another structure interposed therebetween, unless otherwise specified.

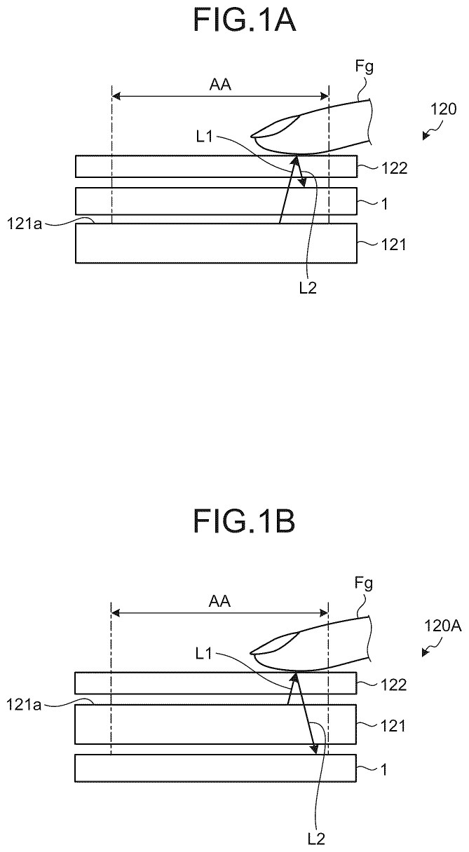

First, with reference to FIGS. 1A and 1B, the following describes application examples of a detection device according to an embodiment of present disclosure.

FIG. 1A is a sectional view illustrating a schematic sectional configuration of a detection apparatus having an illumination device, the detection apparatus including the detection device according to the embodiment. As illustrated in FIG. 1A, a detection apparatus 120 having an illumination device includes a detection device 1 (photodetection device), an illumination device 121, and a cover glass 122. The illumination device 121, the detection device 1, and the cover glass 122 are stacked in this order in a direction orthogonal to a surface of the detection device 1.

The illumination device 121 has a light-emitting surface 121a for emitting light, and emits light L1 from the light-emitting surface 121a toward the detection device 1. The illumination device 121 is a backlight. The illumination device 121 may be, for example, what is called a side light-type backlight that includes a light guide plate provided in a position corresponding to a detection area AA and a plurality of light sources arranged at one end or both ends of the light guide plate. For example, light-emitting diodes (LEDs) that emit light in a predetermined color are used as the light sources. The illumination device 121 may be what is called a direct-type backlight that includes the light sources (such as the LEDs) provided directly below the detection area AA. The illumination device 121 is not limited to the backlight. The illumination device 121 may be provided on a lateral side or an upper side of the detection device 1 and may emit the light L1 to a finger Fg from the lateral side or the upper side of the finger Fg.

The detection device 1 is provided so as to face the light-emitting surface 121a of the illumination device 121. The light L1 emitted from the illumination device 121 passes through the detection device 1 and the cover glass 122. The detection device 1 can detect information on a living body in the finger Fg, a wrist, or the like (hereinafter, also called “biometric information”) by detecting light L2 that has been reflected on or transmitted through the finger Fg, the wrist, or the like of a subject person. The color of the light L1 from the illumination device 121 may be changed depending on the biometric information (such as a pulse wave) that serves as a detection target.

The cover glass 122 is a member for protecting the detection device 1 and the illumination device 121 and covers the detection device 1 and the illumination device 121. The cover glass 122 is a glass substrate, for example. The cover member 122 is not limited to the glass substrate and may be a resin substrate or the like. The cover member 122 need not be provided. In that case, the surface of the detection device 1 is provided with a protective layer, and the finger Fg, the wrist, or the like of the subject person contacts the protective layer of the detection device 1.

FIG. 1B is a sectional view illustrating a schematic sectional configuration of a detection apparatus having an illumination device according to a modification. As illustrated in FIG. 1B, in a detection apparatus 120A having an illumination device, the detection device 1, the illumination device 121, the cover glass 122 are stacked in this order in the direction orthogonal to the surface of the detection device 1. In also the present modification, a display panel such as an organic electroluminescent (EL) display panel can be employed as the illumination device 121.

The light L1 emitted from the illumination device 121 passes through the cover glass 122, and then, is reflected on or transmitted through the finger Fg, the wrist, or the like of the subject person. The light L2 reflected on or transmitted through the finger Fg, the wrist, or the like of the subject person passes through the cover glass 122, and further passes through the illumination device 121. The detection device 1 can detect the biometric information (such as the pulse wave) that serves as the detection target by receiving the light L2 transmitted through the illumination device 121.

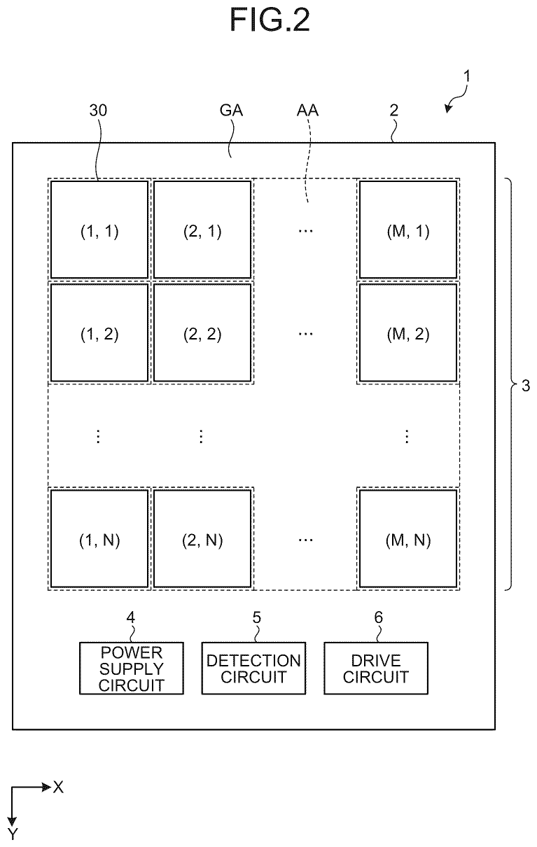

FIG. 2 is a plan view illustrating the detection device according to a comparative example. In the comparative example illustrated in FIG. 2, the detection device includes a sensor 3, a power supply circuit 4, a drive circuit 6, and a detection circuit 5 on a substrate 2.

The substrate 2 has the detection area AA and a peripheral area GA. The detection area AA has a plurality of divided areas 30 arranged in a matrix having a row-column configuration. The detection area AA is an area overlapping the divided areas 30 in the sensor 3. In the comparative example illustrated in FIG. 2, an example is illustrated in which the detection area AA is divided into the divided areas 30 of M columns and N rows in which N columns of the divided areas 30 are arranged in an X direction (first direction) and N rows of the divided areas 30 are arranged in a Y direction (second direction).

The peripheral area GA is an area outside the detection area AA and is an area not overlapping the divided areas 30. That is, the peripheral area GA is an area between the outer perimeter of the detection area AA and the ends of the substrate 2. FIG. 2 illustrates an example in which the power supply circuit 4, the drive circuit 6, and the detection circuit 5 are provided in the peripheral area GA.

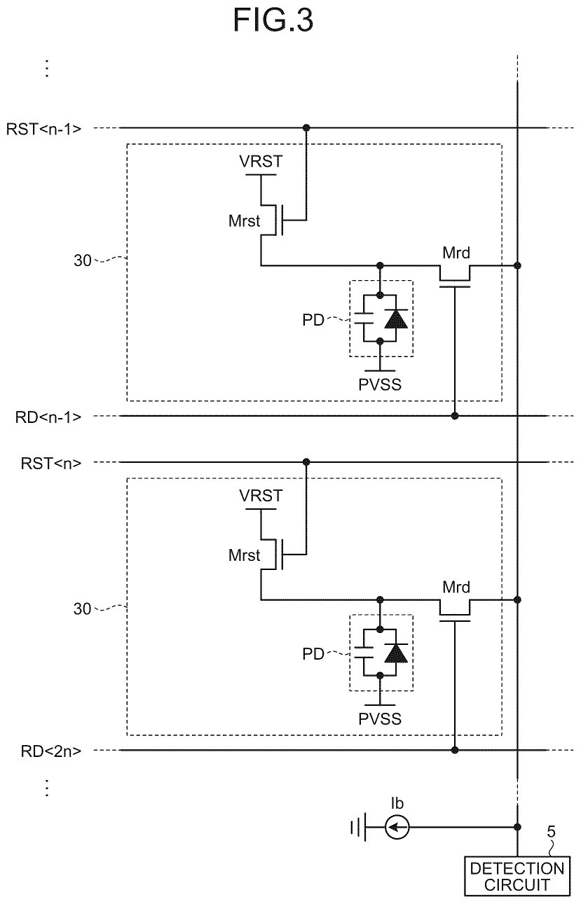

In the comparative example illustrated in FIG. 2, each of the divided areas 30 is provided with an optical sensor PD (refer to FIG. 3). In the present disclosure, the optical sensor PD provided in each of the divided areas 30 is an organic photodiode (OPD). The substrate 2 is provided with an organic semiconductor layer of the optical sensor PD. The organic semiconductor layer is made using a material sensitive to near-infrared light (for example, light having a wavelength of 850 nm). Each of the divided areas 30 is an area provided with the organic semiconductor layer of the optical sensor PD. The organic semiconductor layer of each of the optical sensors PD is insulated by a bank layer (insulating layer). In other words, the organic semiconductor layer of each of the optical sensors PD is provided in an area surrounded by the bank layer.

The power supply circuit 4 is a circuit that supplies various potentials and various power supply voltages to be applied to the divided areas 30. The various potentials and the various power supply voltages applied to the divided areas 30 will be described in the configuration of the divided area 30 to be described later.

The drive circuit 6 is a circuit that outputs various control signals such as a read control signal to the divided area 30 to control operations of the divided area 30. The various control signals such as the read control signal output to the divided area 30 will be described with the configuration of the divided area 30 to be described later.

The detection circuit 5 is a circuit that performs a predetermined detection process based on a signal output from each of the divided areas 30. The detection circuit 5, for example, performs analog-to-digital (AD) conversion on the signal output from the divided area 30 and outputs the converted signal to a processing device or the like at a later stage (not illustrated).

FIG. 3 is a diagram illustrating a configuration in each of the divided areas of the detection device according to the comparative example and an example of coupling to the detection circuit. FIG. 3 illustrates the configuration in each of the divided areas 30 in the mth column of the (n−1)th row and mth column of the nth row. FIG. 3 also illustrates the example of coupling of the divided areas 30 to the detection circuit 5.

As illustrated in FIG. 3, each of the divided areas 30 is provided with the optical sensor PD, a read transistor Mrd, and a reset transistor Mrst. Each of the divided areas 30 is supplied with a power supply potential PVSS and a reset potential VRST from the power supply circuit 4. The power supply potential PVSS is set to 0.75 V, for example. The reset potential VRST is set to 2.75 V, for example.

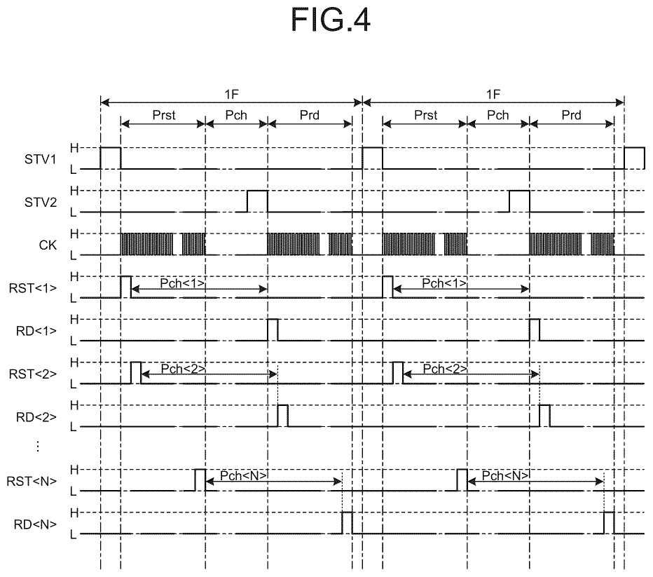

The detection circuit 5 is coupled to a constant current source for applying a bias current Ib to the read transistor Mrd. This configuration makes it possible to detect the output of each of the divided areas 30 via the read transistor Mrd during a read period Prd (refer to FIG. 4). This constant current source may be provided in the detection circuit 5 or in the peripheral area GA of the substrate 2.

The anode of the optical sensor PD is supplied with the power supply potential PVSS. The cathode of the optical sensor PD is supplied with the reset potential VRST via the reset transistor Mrst during a reset period Prst (refer to FIG. 4). As a result, the optical sensor PD is reverse-biased (2.0 V).

The following describes an operation in the configuration according to the comparative example described above. FIG. 4 is a timing diagram illustrating an operation example of the detection device according to the comparative example.

As illustrated in FIG. 4, in the configuration according to the comparative example, the detection device has the reset period Prst, an exposure period Pch, and the read period Prd within one frame period 1F in a detection operation. The power supply circuit 4 supplies the power supply potential PVSS to the anode of the optical sensor PD over the reset period Prst, the exposure period Pch, and the read period Prd.

The drive circuit 6 sequentially controls a reset signal RST<n> to a high potential “H” (hereinafter, controlling a signal to a high potential is also referred to as “H-control”) during the reset period Prst. As a result, the reset transistor Mrst in each of the divided areas 30 is controlled to be on, the reset potential VRST (for example, 2.75 V) is applied to the cathode of the optical sensor PD via the reset transistor Mrst, and the optical sensor PD is reverse-biased (2.0 V). At this time, the optical sensor PD is charged with an electric charge corresponding to the reverse bias voltage.

When the reset signal RST<n> is controlled to a low potential “L” (hereinafter, controlling a signal to a high potential is also referred to as “L-control”), the reset transistor Mrst in each of the divided areas 30 is controlled to be off, and the exposure period Pch of each of the optical sensors PD starts. During this exposure period Pch, a reverse current flows through the optical sensor PD, thereby gradually reducing the electric charge that has been stored in the optical sensor PD during the reset period Prst. The reverse current that flows during the exposure period Pch varies depending on the amount of light that has entered the optical sensor PD.

The drive circuit 6 then sequentially controls a read signal RD<n> to a high potential (H-control) during the read period Prd. As a result, the read transistor Mrd in each of the divided areas 30 is controlled to be on to apply the bias current Ib, and a voltage corresponding to the electric charge stored in the optical sensor PD is detected by the detection circuit 5. The period from when the reset transistor Mrst in each of the divided areas 30 is controlled to be off to when the read transistor Mrd is controlled to be on is referred to as “effective exposure period”.

By repeatedly executing the reset period Prst, the exposure period Pch, and the read period Prd described above over a plurality of frames, the time-varying biometric information such as the pulse wave can be acquired.

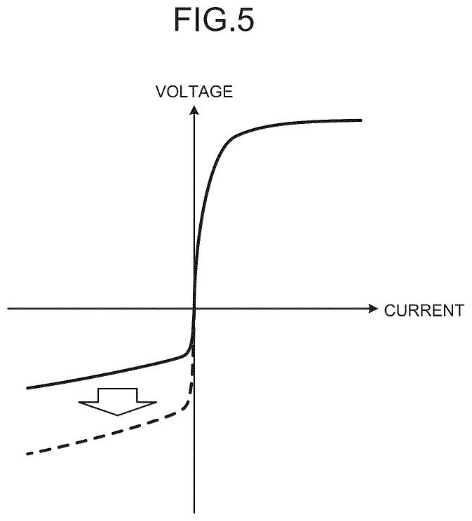

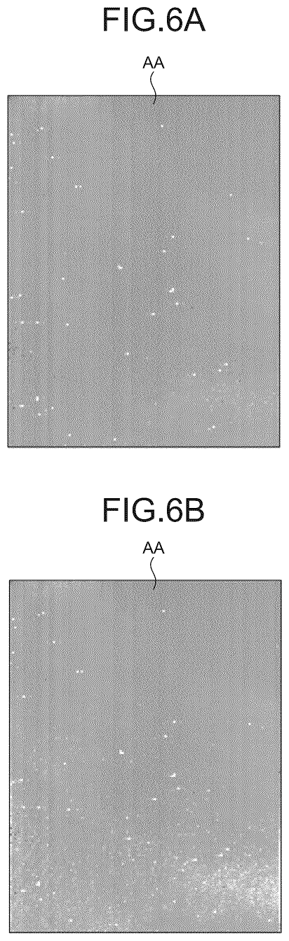

If variations occur in the organic semiconductor layer of the OPD (optical sensor PD), variations may occur in reverse-bias characteristics, and the accuracy of detection may decrease. The following describes the diode characteristics of the optical sensor PD when the variations occur in the organic semiconductor layer, with reference to FIGS. 5, 6A, and 6B.

FIG. 5 is a diagram illustrating an example of the diode characteristics of the optical sensor. In FIG. 5, the horizontal axis indicates current, and the vertical axis indicates voltage. In FIG. 5, a solid line indicates the diode characteristics under normal conditions, and a dashed line indicates an exemplary variation in the characteristics caused by variations in characteristics of the OPD. In FIG. 5, the positive direction of the current is a direction when a forward current is applied through the diode of the optical sensor PD, and the negative direction of the current is a direction when a reverse current is applied through the diode of the optical sensor PD.

FIGS. 6A and 6B are diagrams illustrating examples in which an output level in each of the divided areas is visualized in the detection area. FIG. 6A illustrates an example in which the detection area AA is visualized immediately after the start of the detection operation, and FIG. 6B illustrates an example in which the detection area AA is visualized 15 minutes after the start of the detection operation. In the examples illustrated in FIGS. 6A and 6B, locations where the output level has an abnormal value appear as bright spots.

Variations in the organic semiconductor layer of the OPD may cause the reverse-bias characteristics of the OPD to change over time, as illustrated by the dashed line in FIG. 5. As a result, the reverse current flowing through the optical sensor PD in each of the divided areas 30 during the exposure period Pch (effective exposure period) may vary, thus reducing the accuracy of detection.

In particular, in the configuration in which the time-varying biometric information such as the pulse wave is acquired, observation needs to be performed over a relatively long period of time. In such a configuration, the accuracy is significantly reduced due to the change over time of the reverse-bias characteristics of the OPD, as illustrated in FIG. 6B.

Furthermore, when accurately acquiring time-varying data such as the pulse wave, the detection needs to be performed at a high frame rate.

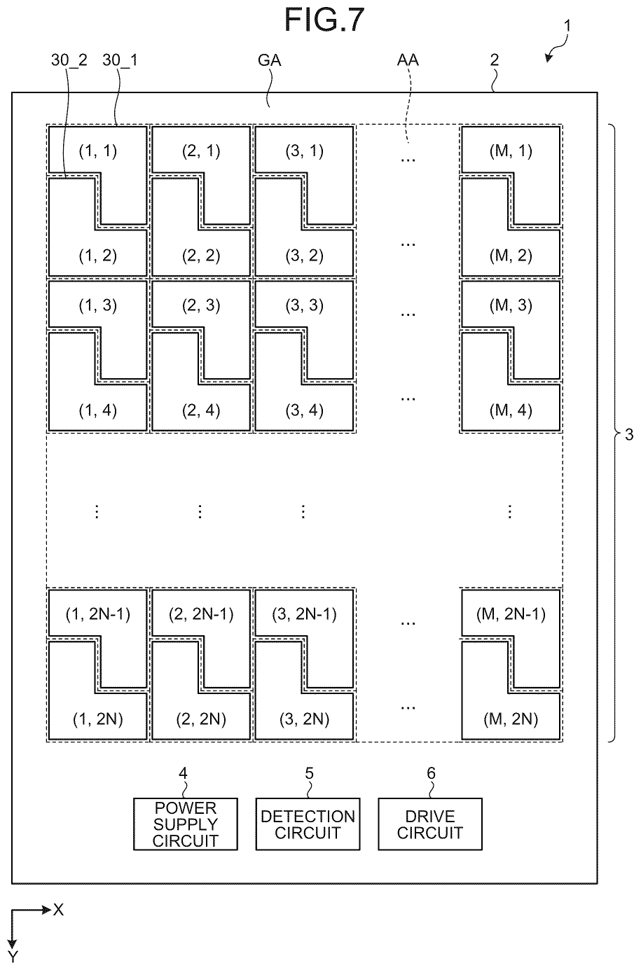

The change over time of the variations in the reverse-bias characteristics of the OPD caused by the variations in the organic semiconductor layer can be eliminated by restoring an initial state of the characteristics of the OPD by forward-biasing the optical sensor PD to apply a forward bias current thereto. In the present disclosure, this operation to restore the initial state of the characteristics of the OPD is referred to as “refresh operation”. The following describes a configuration example and an operation example of the detection device 1 according to the embodiment with reference to FIGS. 7 to 9.

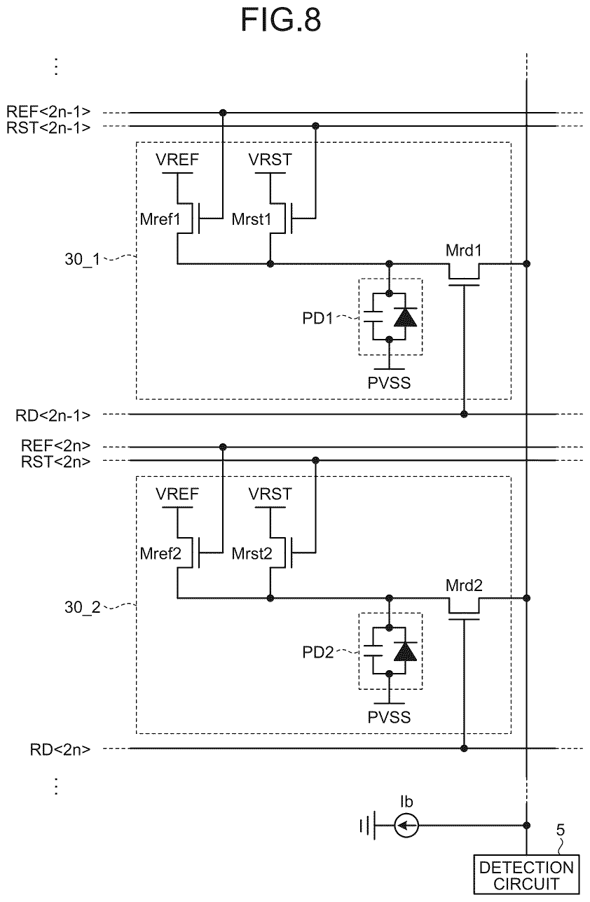

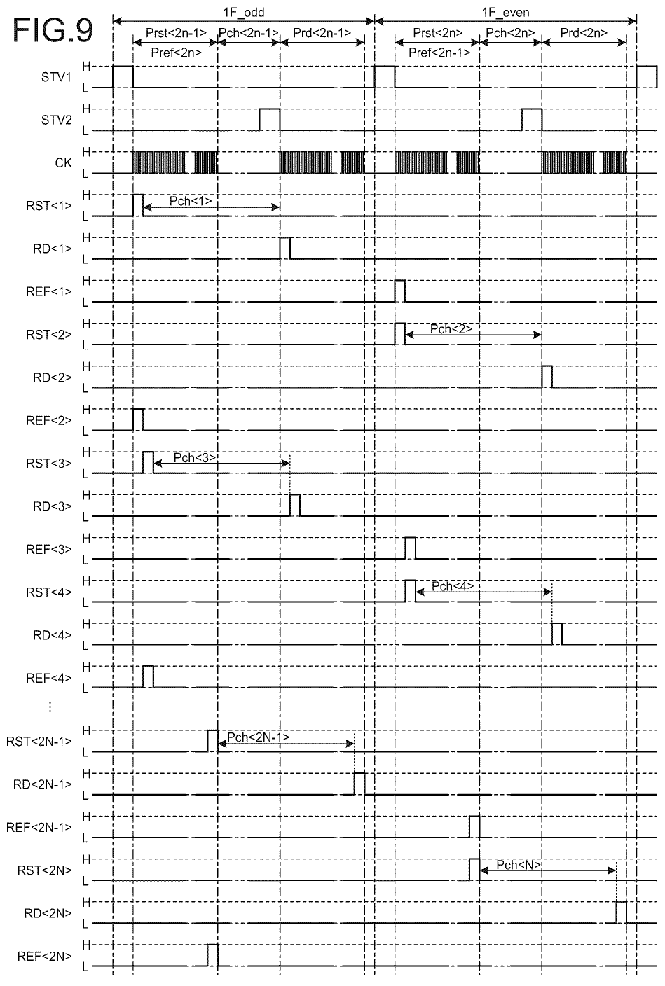

FIG. 7 is a plan view illustrating the detection device according to the embodiment. FIG. 8 is a diagram illustrating a configuration in each of the divided areas of the detection device according to the embodiment and an example of coupling to the detection circuit. FIG. 9 is a timing diagram illustrating the operation example of the detection device according to the embodiment. In the following description, the same components as those in the comparative example described above will not be described.

In the configuration of the detection device 1 according to the embodiment illustrated in FIG. 7, an example is illustrated in which the detection area AA is divided into M columns and 2N rows, where M first divided areas 30_1 are arranged in the X direction (first direction); M second divided areas 30_2 are arranged in the X direction (first direction); and N first divided areas 30_1 and N second divided areas 30_2 are alternately arranged in the Y direction (second direction).

In the detection device 1 according to the embodiment, as illustrated in FIG. 7, the first divided area 30_1 having an inverted L shape in odd-numbered rows (rows 2n−1) and the second divided area 30_2 having an L shape in even-numbered rows (rows 2n) that are adjacent to each other are combined so as to partially overlap each other in the X direction (first direction).

As illustrated in FIG. 8, each of the first divided areas 30_1 is provided with a first optical sensor PD1, a read transistor Mrd1, and a reset transistor Mrst1 (second transistor). The first divided area 30_1 is supplied with the power supply potential PVSS (first potential) and the reset potential VRST (third potential) from the power supply circuit 4. The power supply potential PVSS (first potential) is set to 0.75 V, for example. The reset potential VRST (third potential) is set to 2.75 V, for example.

As illustrated in FIG. 8, the first divided area 30_1 of the detection device 1 according to the embodiment is provided with a refresh transistor Mref1 (first transistor) in addition to the configuration of the comparative example illustrated in FIG. 3. The first divided area 30_1 is supplied with a refresh potential VREF from the power supply circuit 4. The refresh potential VREF is set to −1.25 V, for example.

As illustrated in FIG. 8, each of the second divided areas 30_2 is provided with a second optical sensor PD2, a read transistor Mrd2, and a reset transistor Mrst2 (fourth transistor). The second divided area 30_2 is supplied with the power supply potential PVSS (first potential) and the reset potential VRST (third potential) from the power supply circuit 4.

As illustrated in FIG. 8, the second divided area 30_2 of the detection device 1 according to the embodiment is provided with a refresh transistor Mref2 (third transistor) in addition to the configuration of the comparative example illustrated in FIG. 3. The second divided area 30_2 is supplied with the refresh potential VREF from the power supply circuit 4.

The cathodes of the first and the second optical sensors PD1 and PD2 are supplied with a refresh potential (second potential) VREF via the refresh transistors Mref1 and Mref2 during refresh periods Pref<2n−1> and Pref<2n> (refer to FIG. 9). As a result, the first and the second optical sensors PD1 and PD2 are forward-biased (2.0 V).

As illustrated in FIG. 9, within an odd-numbered frame period 1F_odd (first period) in the detection operation, the detection device 1 according to the embodiment has a reset period Prst<2n−1>, an exposure period Pch<2n−1>, and a read period Prd<2n−1> for the first optical sensors PD1 in the first divided areas 30_1 in the odd-numbered rows (rows 2n−1). The detection device 1 according to the embodiment also has a refresh period Pref<2n> for the second optical sensors PD2 in the second divided areas 30_2 in the even-numbered rows (rows 2n) within the odd-numbered frame period 1F_odd (first period) in the detection operation.

The drive circuit 6 sequentially controls a reset signal RST<2n−1> to a high potential (H-control) during the reset period Prst<2n−1>. As a result, the reset transistor Mrst1 (second transistor) in each of the first divided areas 30_1 in the odd-numbered rows (rows 2n−1) is controlled to be on; the reset potential VRST (for example, 2.75 V) is applied to the cathode of the first optical sensor PD1 in each of the first divided areas 30_1 in the odd-numbered rows (rows 2n−1) via the reset transistor Mrst1 (second transistor); and the first optical sensor PD1 in each of the first divided areas 30_1 in the odd-numbered rows (rows 2n−1) is reverse-biased (2.0 V). At this time, the first optical sensor PD1 in each of the first divided areas 30_1 in the odd-numbered rows (rows 2n−1) is charged with an electric charge corresponding to the reverse bias voltage.

The drive circuit 6 sequentially controls a refresh signal REF<2n> to a high potential (H-control) during the refresh period Pref<2n>. As a result, the refresh transistor Mref2 (third transistor) in each of the second divided areas 30_2 in the even-numbered rows (rows 2n) is controlled to be on; the refresh potential VREF (for example, −1.25 V) is applied to the cathode of the second optical sensor PD2 in each of the second divided areas 30_2 in the even-numbered rows (rows 2n) via the refresh transistor Mref2 (third transistor); and the second optical sensor PD2 in each of the second divided areas 30_2 in the even-numbered rows (rows 2n) is forward-biased (2.0 V). Consequently, the reverse-bias characteristics of the second optical sensor PD2 in each of the second divided areas 30_2 in the even-numbered rows (rows 2n) can be restored to the initial state. The reset period Prst<2n−1> in the odd-numbered rows (rows 2n−1) and the refresh period Pref<2n> in the even-numbered rows (rows 2n) have overlapping periods.

When the reset signal RST<2n−1> is controlled to a Low potential (L-control), the reset transistor Mrst1 (second transistor) in each of the first divided areas 30_1 in the odd-numbered rows (rows 2n−1) is controlled to be off, and the exposure period Pch<2n−1> of each of the first optical sensors PD1 in the first divided areas 30_1 in the odd-numbered rows (rows 2n−1) starts. During this exposure period Pch<2n−1>, a reverse current flows through the first optical sensor PD1 in each of the first divided areas 30_1 in the odd-numbered rows (rows 2n−1), thereby gradually reducing the electric charge that has been stored in the first optical sensor PD1 in each of the first divided areas 30_1 in the odd-numbered rows (rows 2n−1) during the reset period Prst<2n−1>.

The drive circuit 6 then sequentially controls a read signal RD<2n−1> to a high potential (H-control) during the read period Prd<2n−1>. As a result, the read transistor Mrd1 in each of the first divided areas 30_1 in the odd-numbered rows (rows 2n−1) is controlled to be on to apply the bias current Ib, and a voltage corresponding to the electric charge stored in the first optical sensor PD1 in each of the first divided areas 30_1 in the odd-numbered rows (rows 2n−1) is detected by the detection circuit 5.

As illustrated in FIG. 9, within an even-numbered frame period 1F_even (second period) in the detection operation, the detection device 1 according to the embodiment has a reset period Prst<2n>, an exposure period Pch<2n>, and a read period Prd<2n> for the second optical sensors PD2 in the second divided areas 30_2 in the even-numbered rows (rows 2n). The detection device 1 according to the embodiment also has a refresh period Pref<2n−1> for the first optical sensors PD1 in the first divided areas 30_1 in the odd-numbered rows (rows 2n−1) within the even-numbered frame period 1F_even (second period) in the detection operation.

The drive circuit 6 sequentially controls a reset signal RST<2n> to a high potential (H-control) during the reset period Prst<2n>. As a result, the reset transistor Mrst2 (fourth transistor) in each of the second divided areas 30_2 in the even-numbered rows (rows 2n) is controlled to be on; the reset potential VRST (third potential) is applied to the cathode of the second optical sensor PD2 in each of the second divided areas 30_2 in the even-numbered rows (rows 2n) via the reset transistor Mrst2 (fourth transistor); and the second optical sensor PD2 in each of the second divided areas 30_2 in the even-numbered rows (rows 2n) is reverse-biased (2.0 V). At this time, the second optical sensor PD2 in each of the second divided areas 30_2 in the even-numbered rows (rows 2n) is charged with an electric charge corresponding to the reverse bias voltage.

The drive circuit 6 sequentially controls a refresh signal REF<2n−1> to a high potential (H-control) during the refresh period Pref<2n−1>. As a result, the refresh transistor Mref1 (first transistor) in each of the first divided areas 30_1 in the odd-numbered rows (rows 2n−1) is controlled to be on; the refresh potential VREF (for example, −1.25 V) is applied to the cathode of the first optical sensor PD1 in each of the first divided areas 30_1 in the odd-numbered rows (rows 2n−1) via the refresh transistor Mref (first transistor); and the first optical sensor PD1 in each of the first divided areas 30_1 in the odd-numbered rows (rows 2n−1) is forward-biased (2.0 V). Consequently, the reverse-bias characteristics of the first optical sensor PD1 in each of the first divided areas 30_1 in the odd-numbered rows (rows 2n−1) can be restored to the initial state. The reset period Prst<2n> in the even-numbered rows (rows 2n) and the refresh period Pref<2n−1> in the odd-numbered rows (rows 2n−1) have overlapping periods.

When the reset signal RST<2n> is controlled to a low potential (L-control), the reset transistor Mrst2 (fourth transistor) in each of the second divided areas 30_2 in the eve-numbered rows (rows 2n) is controlled to be off, and the exposure period Pch<2n> of each of the second optical sensors PD2 in the second divided areas 30_2 in the even-numbered rows (rows 2n) starts. During this exposure period Pch<2n>, a reverse current flows through the second optical sensor PD2 in each of the second divided areas 30_2 in the even-numbered rows (rows 2n), thereby gradually reducing the electric charge that has been stored in the second optical sensor PD2 in each of the second divided areas 30_2 in the even-numbered rows (rows 2n) during the reset period Prst<2n>.

The drive circuit 6 then sequentially controls a read signal RD<2n> to a high potential (H-control) during the read period Prd<2n>. As a result, the read transistor Mrd2 in each of the second divided areas 30_2 in the even-numbered rows (rows 2n) is controlled to be on to apply the bias current Ib, and a voltage corresponding to the electric charge stored in the second optical sensor PD2 in each of the second divided areas 30_2 in the even-numbered rows (rows 2n) is detected by the detection circuit 5.

By alternately and repeatedly executing of the odd-numbered frame period 1F_odd (first period) and the even-numbered frame period 1F_even (second period) described above, the detection operation of the first optical sensor PD1 in each of the first divided areas 30_1 in the odd-numbered rows (rows 2n−1) and the detection operation of the second optical sensor PD2 in each of the second divided areas 30_2 in the even-numbered rows (rows 2n) are alternately performed. The refresh operation of the second optical sensor PD2 in each of the second divided areas 30_2 in the even-numbered rows (rows 2n) is performed in the odd-numbered frame period 1F_odd (first period) in which the detection operation of the first optical sensor PD1 in each of the first divided areas 30_1 in the odd-numbered rows (rows 2n−1) is being performed. The refresh operation of the first optical sensor PD1 in each of the first divided areas 30_1 in the odd-numbered rows (rows 2n−1) is performed in the even-numbered frame period 1F even (second period) in which the detection operation of the second optical sensor PD2 in each of the second divided areas 30_2 in the even-numbered rows (rows 2n) is being performed. This operation allows accurate acquisition of the time-varying biometric information such as the pulse wave without reducing the frame rate.

The example of the division in the detection area AA is not limited to the configuration in which the first divided areas 30_1 having an inverted L shape in the odd-numbered rows (rows 2n−1) is combined with the second divided areas 30_2 having an L shape in the even-numbered rows (rows 2n) so as to partially overlap each other in the X direction (first direction), as illustrated in FIG. 7. In the description of each of the following modifications, the same components as those in the embodiment described above will not be described.

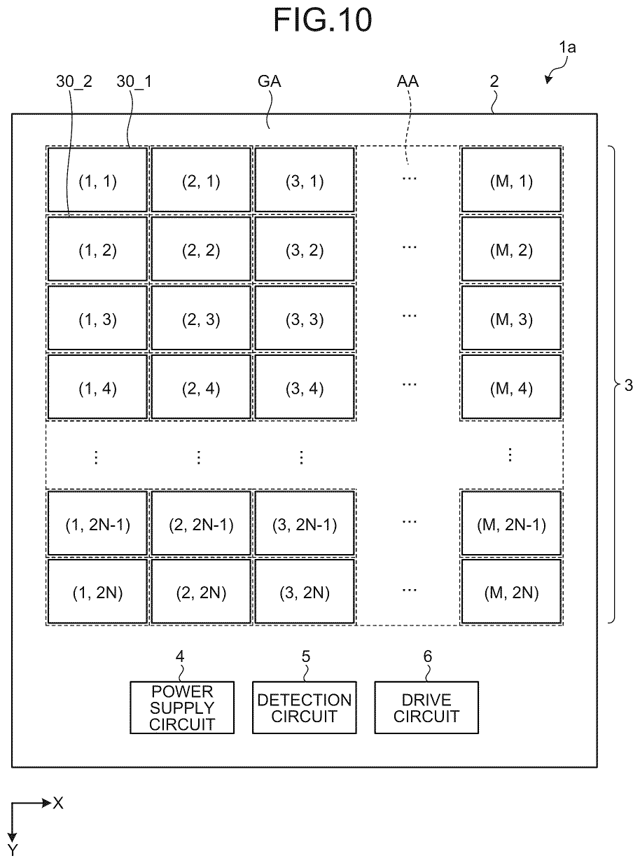

FIG. 10 is a plan view illustrating a detection device according to a first modification of the embodiment. The configuration of a detection device 1a according to the first modification of the embodiment illustrated in FIG. 10 illustrates an example in which the rectangular first and second divided areas 30_1 and 30_2 are arranged in a matrix having a row-column configuration in the detection area AA in the same manner as the comparative example illustrated in FIG. 2.

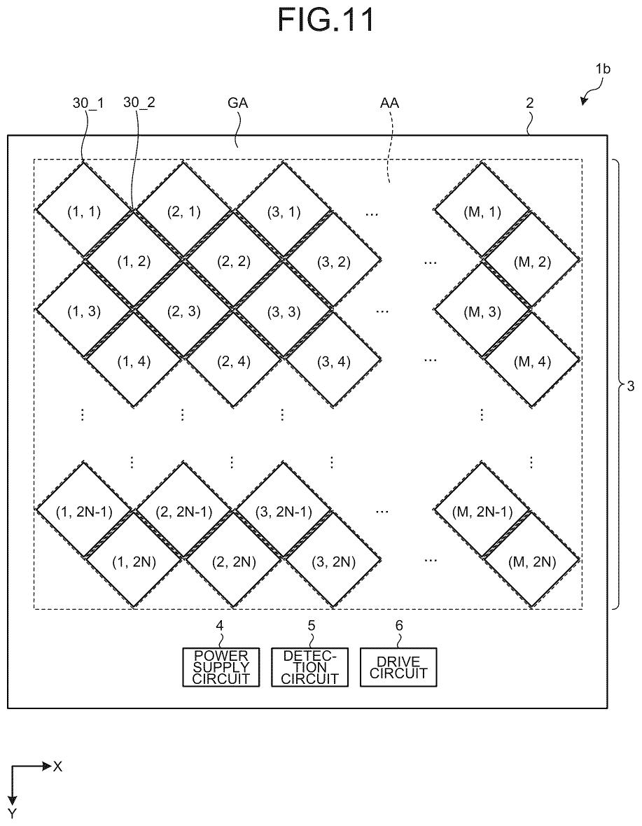

FIG. 11 is a plan view illustrating a detection device according to a second modification of the embodiment. As illustrated in FIG. 11, the configuration of a detection device 1b according to the second modification of the embodiment illustrates an example in which the first and second divided areas 30_1 and 30_2 each having a rhombic shape are arranged in a staggered manner in the detection area AA. In other words, in the detection area AA, the positions in the X direction (first direction) of the second divided areas 30_2 are arranged to be shifted from the positions in the X direction (first direction) of the first divided areas 30_1. In this configuration, the first divided area 30_1 in the odd-numbered rows (rows 2n−1) and the second divided area 30_2 in the even-numbered rows (rows 2n) that are adjacent to each other are combined so as to partially overlap each other in the X direction (first direction), in the same manner as in the configuration illustrated in FIG. 7. The positions in the Y direction (second direction) of the second divided areas 30_2 are arranged to be shifted from the positions in the Y direction (second direction) of the first divided areas 30_1.

The components in the embodiments described above can be combined with one another as appropriate. Other operational advantages accruing from the aspects described in the embodiment herein that are obvious from the description herein or that are appropriately conceivable by those skilled in the art will naturally be understood as accruing from the present invention.

What is claimed is:

1. A detection device comprising:
a sensor comprising a first photodiode and a second photodiode; and
a detection circuit configured to alternately detect an output of the first photodiode and an output of the second photodiode, wherein
anodes of the first photodiode and the second photodiode are configured to be supplied with a first potential,
a cathode of the second photodiode is configured to be supplied with a second potential lower than the first potential in a first period in which the output of the first photodiode is detected, and
a cathode of the first photodiode is configured to be supplied with the second potential in a second period in which the output of the second photodiode is detected.

2. The detection device according to claim 1, wherein
the cathode of the first photodiode is configured to be supplied with a third potential higher than the first potential in the first period, and
the cathode of the second photodiode is configured to be supplied with the third potential in the second period.

3. The detection device according to claim 2, wherein
the sensor has a detection area that has a first divided area provided with the first photodiode and a second divided area provided with the second photodiode, and
the first divided area is adjacent to the second divided area in the detection area.

4. The detection device according to claim 3, wherein
the first divided area is provided with:
a first transistor configured to supply the second potential to the cathode of the first photodiode; and
a second transistor configured to supply the third potential to the cathode of the first photodiode, and
the second divided area is provided with:
a third transistor configured to supply the second potential to the cathode of the second photodiode; and
a fourth transistor configured to supply the third potential to the cathode of the second photodiode.

5. The detection device according to claim 4, wherein
the fourth transistor is configured to be controlled to be on when the first transistor is controlled to be on, and
the second transistor is configured to be controlled to be on when the third transistor is controlled to be on.

6. The detection device according to claim 3, wherein
the sensor has a plurality of the first divided areas and a plurality of the second divided areas,
the first divided areas are arranged in a first direction,
the second divided areas are arranged in the first direction, and
the first divided areas and the second divided areas are provided so as to be alternately arranged in a second direction different from the first direction.

7. The detection device according to claim 6, wherein the first divided area and the second divided area that are adjacent to each other are provided so as to partially overlap each other in the first direction.

8. The detection device according to claim 3, wherein
the sensor has a plurality of the first divided areas and a plurality of the second divided areas,
the first divided areas are arranged in a first direction,
the second divided areas are arranged in the first direction, and
in the detection area, positions in the first direction of the second divided areas are arranged to be shifted from positions in the first direction of the first divided areas.

9. The detection device according to claim 3, wherein the first photodiode and the second photodiode are organic photodiodes.

10. The detection device according to claim 9, wherein an organic semiconductor layer is provided in each of the first divided area and the second divided area.

11. The detection device according to claim 10, wherein the organic semiconductor layer in the first divided area is insulated from the organic semiconductor layer in the second divided area.

12. The detection device according to claim 1, wherein
the first period comprises:
a refresh period in which the cathode of the second photodiode is supplied with the second potential;
an exposure period in which the first photodiode is exposed to light; and
a read period in which an electric charge stored in the first photodiode is read,
the second period comprises:
a refresh period in which the cathode of the first photodiode is supplied with the second potential;
an exposure period in which the second photodiode is exposed to light; and
a read period in which an electric charge stored in the second photodiode is read,
the cathode of the first photodiode is supplied with a third potential higher than the first potential in the refresh period of the first period, and
the cathode of the second photodiode is supplied with the third potential in the refresh period of the second period.
